(19) United States
(12) Patent Application Publication
(10) Pub. No.: US 2025/0293191 A1
(43) Pub. Date: Sep. 18, 2025

(54) METHOD AND SYSTEM FOR ASSEMBLING MICROELECTRONIC COMPONENTS

(71) Applicant: TRIPLE WIN TECHNOLOGY (SHENZHEN) CO. LTD., Shenzhen (CN)

(72) Inventor: BIN-KAI WANG, Shenzhen (CN)

(21) Appl. No.: 19/027,321

(22) Filed: Jan. 17, 2025

(30) Foreign Application Priority Data
Mar. 13, 2024 (CN) 202410288604.4

(51) Int. Cl. H01L 23/00; H01L 21/67

(52) U.S. Cl. CPC H01L 24/27; H01L 21/67144; H01L 24/743; H01L 24/83; H01L 2224/27318; H01L 2224/743; H01L 2224/83143

(57) ABSTRACT

The present disclosure provides a method and a system for assembling microelectronic components. The method includes: a substrate including a first surface is provided, the first surface includes a plurality of first areas and a second area surrounding each first area, the first area has a lyophilic surface, and the second area has a lyophobic surface; a plurality of adhesive liquid droplets automatically form on the first areas; and a plurality of microelectronic components on a carrier plate transferred onto the adhesive liquid droplets, wherein the microelectronic components are automatically aligned with the first areas to obtain an assembled structure.

### FIELD

The subject matter relates to the assembly of the microelectronic component, and more particularly, to a method for assembling microelectronic components and a system for assembling the microelectronic components.

### BACKGROUND

Existing display devices such as LED display devices, OLED display devices and LCD display devices may not meet the high demand for display performance. The MicroLED display device may have better performance than the existing display devices in terms of brightness, resolution, contrast, power consumption and service life. Thus, the MicroLED display device may become the next mainstream display device.

However, the size of the MicroLED display device is large. Moreover, the efficiency and yield of the assembling process of the MicroLED display device may not meet the requirements.

Therefore, there is room for improvement in the art.

### BRIEF DESCRIPTION OF THE DRAWINGS

Implementations of the present technology will now be described, by way of example only, with reference to the attached figures.

FIG. 1A is a flowchart of an embodiment of a method for assembling microelectronic components according to an embodiment of the present disclosure.

FIG. 1B is a diagrammatic view of a microelectronic component assembled structure according to an embodiment of the present disclosure.

FIG. 1C is a flowchart of an embodiment of a method for applying adhesive liquid droplets onto first areas by an adhesive application device according to an embodiment of the present disclosure.

FIG. 1D is a flowchart of an embodiment of a method for transferring microelectronic components from a carrier plate onto the adhesive liquid droplets by a release device according to an embodiment of the present disclosure.

FIG. 2 is a diagrammatic view of a substrate according to an embodiment of the present disclosure.

FIG. 3 is a diagrammatic view showing an adhesive application device transferred above the substrate of FIG. 2.

FIG. 4 is a diagrammatic view showing an adhesive applied onto the substrate by the adhesive application device of FIG. 3.

FIG. 5 is a diagrammatic view showing adhesive liquid droplets formed on the first areas of the substrate of FIG. 4.

FIG. 6 is a diagrammatic view showing a carrier plate arranged above the substrate and a laser device arranged above the carrier plate of FIG. 5.

FIG. 7 is a diagrammatic view showing microelectronic components released from the carrier plate by the laser device of FIG. 6.

FIG. 8 is a diagrammatic view showing all microelectronic components released onto the adhesive liquid droplets on the substrate of FIG. 7.

FIG. 9 is a top view of one adhesive liquid droplet applied onto a corresponding first area of the substrate of FIG. 5.

FIG. 10 is a top view showing the microelectronic component released onto the adhesive liquid droplet on the substrate of FIG. 9.

FIG. 11 is a top view showing the microelectronic component aligned with the corresponding first area of FIG. 10.

FIG. 12 is a block diagram of an assembly system for assembling microelectronic components according to an embodiment of the present disclosure.

### DETAILED DESCRIPTION

It will be appreciated that for simplicity and clarity of illustration, where appropriate, reference numerals have been repeated among the different FIG.s to indicate corresponding or analogous components. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so- described combination, group, series, and the like.

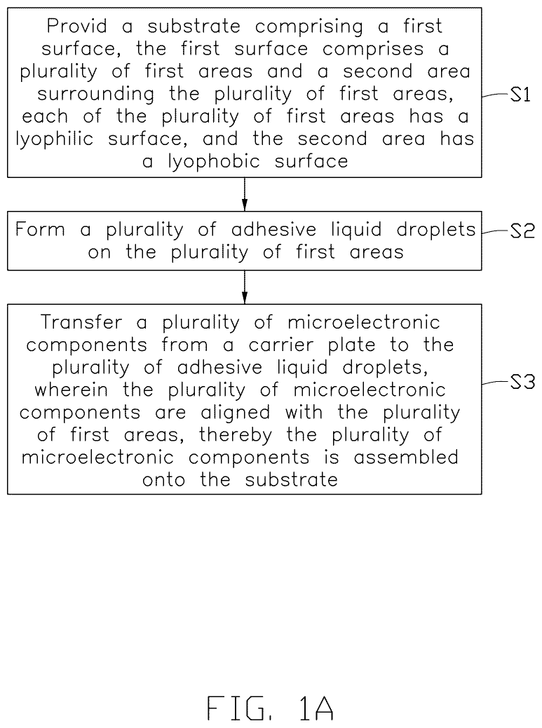

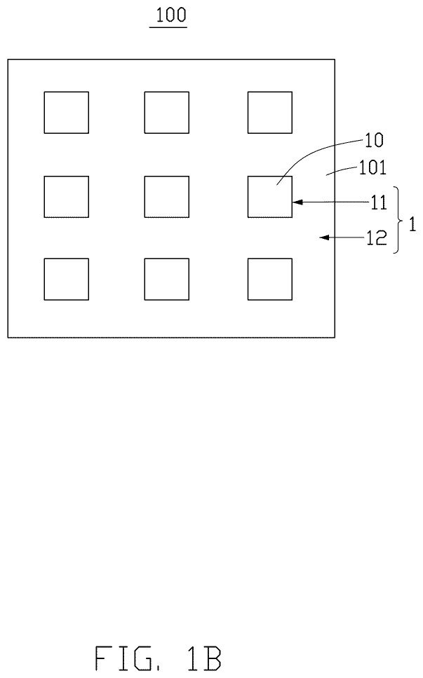

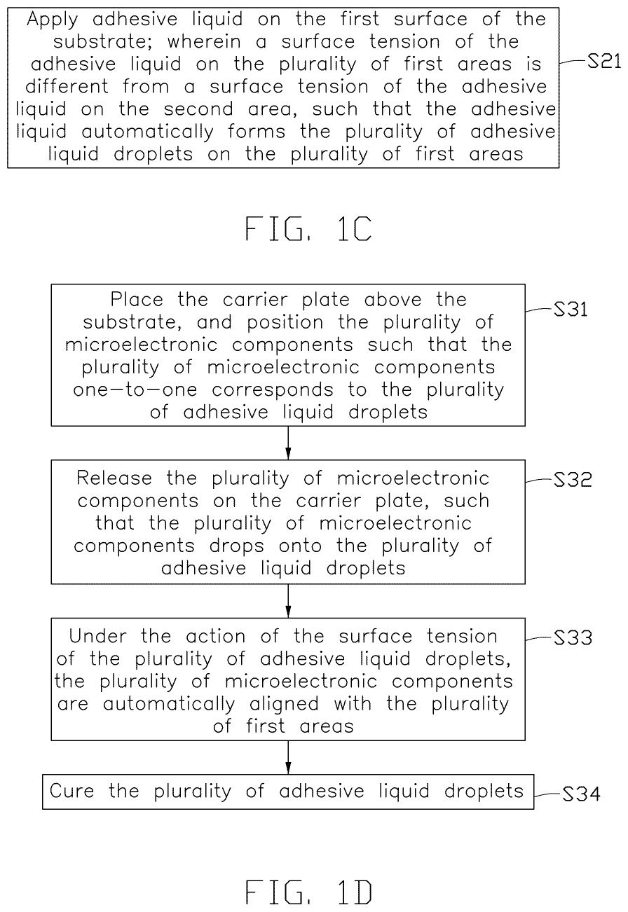

FIG. 1A illustrates a flowchart of a method for assembling microelectronic components is provided according to the present disclosure. FIG. 1B illustrates a microelectronic component assembled structure 100 formed by the method of FIG. 1A. The method is provided by way of embodiment, as there are a variety of ways to carry out the method. The method can begin at block S1.

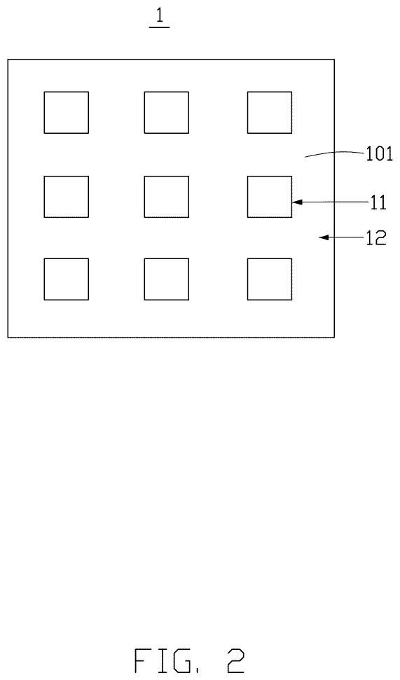

Block S1, referring to FIG. 2, a substrate 1 is provided. The substrate 1 includes a first surface 101. The first surface 101 includes a plurality of first areas 11 and a second area 12. The second area 12 is located around each first area 11. The first area 11 has a lyophilic surface, and the second area 12 has a lyophobic surface. A “lyophilic surface” can be understood as a surface that is easily wetted by liquid. A “lyophobic surface” can be understood as a surface that is not easily wetted by liquid. Therefore, the wettability of the first area 11 by liquid is better than that of the second area 12.

Referring to FIG. 1B, the substrate 1 is used to assemble microelectronic components 10 thereon to form the microelectronic components assembled structure 100.

In an embodiment, the microelectronic component is a MicroLED. The above method is used to transfer and assembly the MicroLEDs to form a MicroLED assembled structure. In another embodiment, the microelectronic component can also be a chip with small volume.

In an embodiment, a surface of the microelectronic component 10 faced to the first area 11 is substantially a plane.

There is a difference in the wettability of the first area 11 and the second area 12. That is, the wettability of the first area 11 by liquid is better than that of the second area 12 by liquid, such that the substrate 1 with different wettability zones are formed. Since the wettability of the first area 11 by liquid is better, the liquid has a small surface tension on the first area 11. Since the wettability of the second area 12 by liquid is worse, the liquid has a large surface tension on the second area 12. For example, taking water as an example, the first area 11 is a hydrophilic area or a super-hydrophilic area, and the second area 12 is a hydrophobic area or a super-hydrophobic area. It can be understood that the substrate 1 with different wettability zones may also be formed by different liquid media. For example, the first area 11 may also be an adhesive-friendly area, and the second area 12 may also be an adhesive-repellent area.

In an embodiment, the substrate 1 with different wettability zones can be prepared by a physical method, a chemical method, or a combination thereof. For example, a laser micromachining method can be used to regulate the surface wettability of different areas of the substrate 1. A mask spraying method can be used to spray corresponding liquids on different areas of the substrate 1 to form films with corresponding wettability.

In an embodiment, referring to FIGS. 1B and 2, the first areas 11 can be arranged in an array.

In an embodiment, the first area 11 can be rectangular, circular or other shapes. In this embodiment, the first area 11 is substantially rectangular. The first area 11 with rectangular shape is convenient for molding and easily matches the shape of the microelectronic component 10.

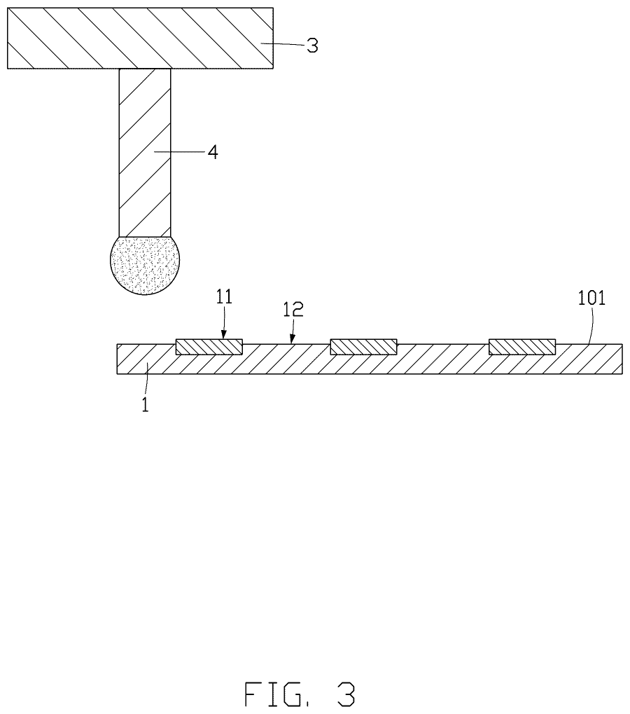

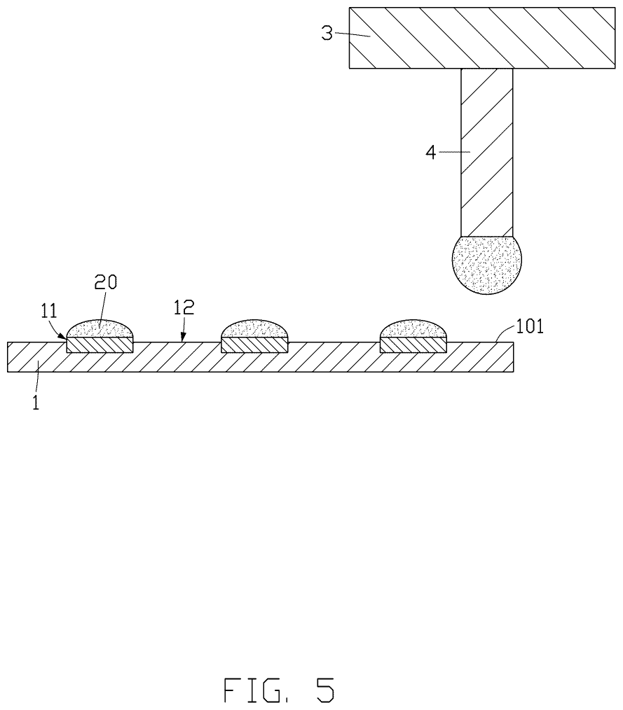

Black S2, referring to FIGS. 3 to 5, a plurality of adhesive liquid droplets 20 is automatically formed on each of the first areas 11.

In an embodiment, referring to FIG. 1C, a method for automatically forming the adhesive liquid droplets 20 on the first areas 11 is provided by way of example. The method can begin at block S21.

Black S21, referring to FIGS. 3 to 5, adhesive liquid is applied on the first surface 101 of the substrate 1. Wherein a surface tension of the adhesive liquid on the first area 11 is different from a surface tension of the adhesive liquid on the second area 12, such that the adhesive liquid automatically forms the adhesive liquid droplets 20 on the first areas 11.

In an embodiment, an adhesive application device 3 can be used to apply the adhesive liquid on the first surface 101. A needle 4 of the adhesive application device 3 is suspended above the substrate 1, and a distance from the first surface 101 can be adjusted according to actual needs.

A relative movement is formed between the adhesive application device 3 and the substrate 1. During the relative movement, the adhesive liquid in the adhesive application device 3 is applied on the first surface 101. At this time, the adhesive liquid is applied in the first area 11 and/or the second area 12.

In an embodiment, the adhesive application device 3 can move relative to the substrate 1. A precision moving platform can be used to drive the needle 4 on the adhesive application device 3 to move above the substrate 1, thereby forming the relative movement.

In another embodiment, the substrate 1 can move relative to the adhesive application device 3. The substrate 1 can be moved by the precision moving platform.

In an embodiment, the adhesive application device 3 may include a plurality of needles 4 arranged side by side above the substrate 1. In this way, the needles 4 can simultaneously distribute the adhesive liquid droplets onto the substrate 1 including multiple first areas 11, thereby improving the liquid droplet distribution efficiency and distribution amount.

Referring to FIGS. 3 to 5, the adhesive liquid has different surface tensions on the first area 11 and the second area 12. Under the action of the surface tension, the adhesive liquid automatically forms the adhesive liquid droplet 20 located on the corresponding first area 11.

In an embodiment, when the adhesive application device 3 applies the adhesive liquid 20, the adhesive liquid 20 may be strictly applied on the first area 11. Since the first area 11 has a lyophilic surface, the adhesive liquid can directly attracted to the first area 11 to form the adhesive liquid droplet 20.

In another embodiment, the adhesive liquid can also be applied on the second area 12. Wherein, a surface tension of the adhesive liquid on the first areas 11 is different from a surface tension of the adhesive liquid on the second area 12, such that the adhesive liquid forms a plurality of adhesive liquid droplets 20 on the lyophobic second area 12, and the adhesive liquid droplet 20 finally moves to the first areas 11 with greater wettability under the action of different surface tensions.

In yet another embodiment, the adhesive liquid can also be directly coated on the first surface 101 of the substrate 1. At this time, the adhesive liquid may exist on both the first area 11 and the second area 12. Due to different wettability of different areas of the substrate 1, the adhesive liquid located on the second area 12 can automatically form an adhesive liquid droplets 20 and move to the first areas 11.

Since the adhesive liquid has different surface tensions on the first area 11 and the second area 12, when the adhesive liquid is applied on the second area 12, under the action of surface tension, the adhesive liquid can automatically form the adhesive liquid droplet 20 on the lyophobic surface of the second area 12 and moves onto the first area 11.

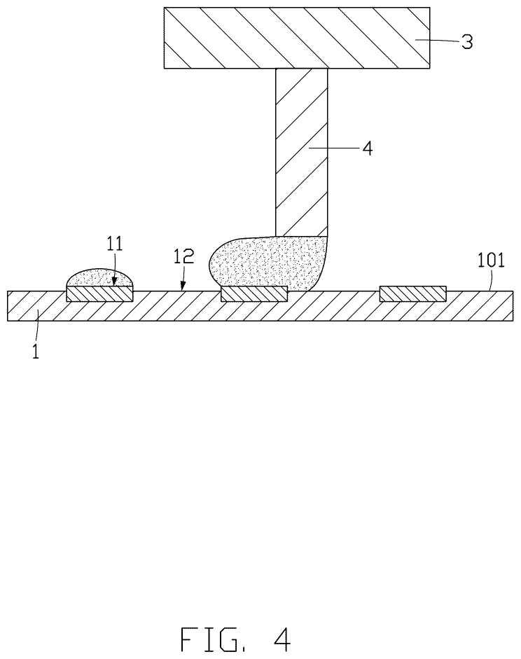

Referring to FIGS. 3 and 4, the precision moving platform drives the needle 4 to move above the substrate 1, so that the adhesive liquid flowing out from the needle 4 passes over the first surface 101 of the substrate 1. As mentioned above, the wettability of the first area 11 and the second area 12 is different, so that under the action of surface tension, the adhesive liquid can form droplets and be automatically distributed onto the first areas 11 with greater wettability. In this way, the automatic distribution of adhesive liquid droplets 20 on the substrate 1 can be realized. The droplet distribution efficiency is high and a volume of the adhesive liquid droplet 20 can be controlled accurately. The adhesive application device 3 has a simple structure, low cost, and is simple and convenient to operate.

In an embodiment, the volume of the adhesive liquid droplet 20 corresponds to a surface area of the first area 11. The volume of the adhesive liquid droplet 20 can be controlled according to the surface area of the first area 11. The surface area of the first area 11 is designed according to the installation area of microelectronic components 10 to be assembled. Thus, the amount of the adhesive liquid droplets 20 can accurately controlled. When the microelectronic components 10 is subsequently assembled onto the first areas 11, the adhesive liquid droplet 20 is exactly located below the microelectronic component 10.

In an embodiment, the adhesive liquid can be a conductive adhesive liquid. By forming the conductive adhesive on the first areas 11, the microelectronic components 10 can be fixed on the substrate 1, and at the same time, the electrical connection between the microelectronic components 10 and the substrate 1 can be realized.

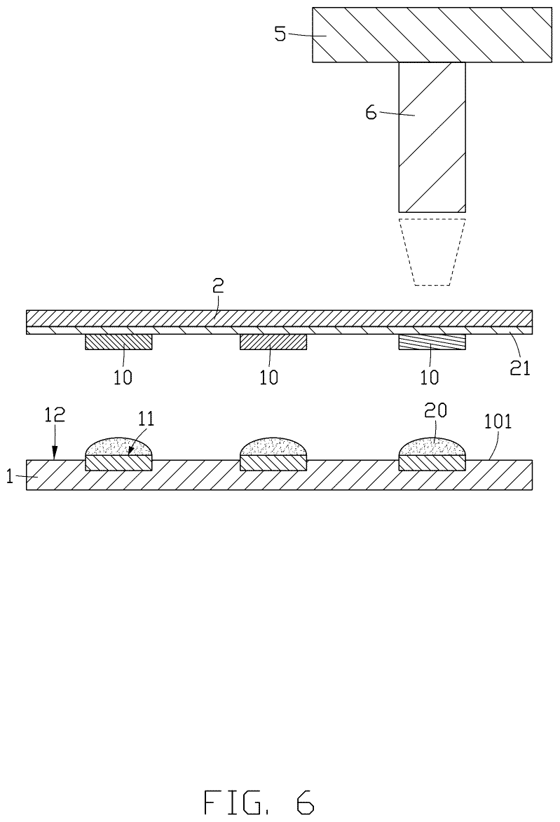

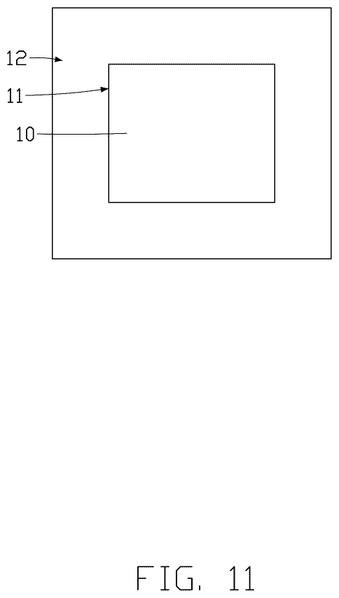

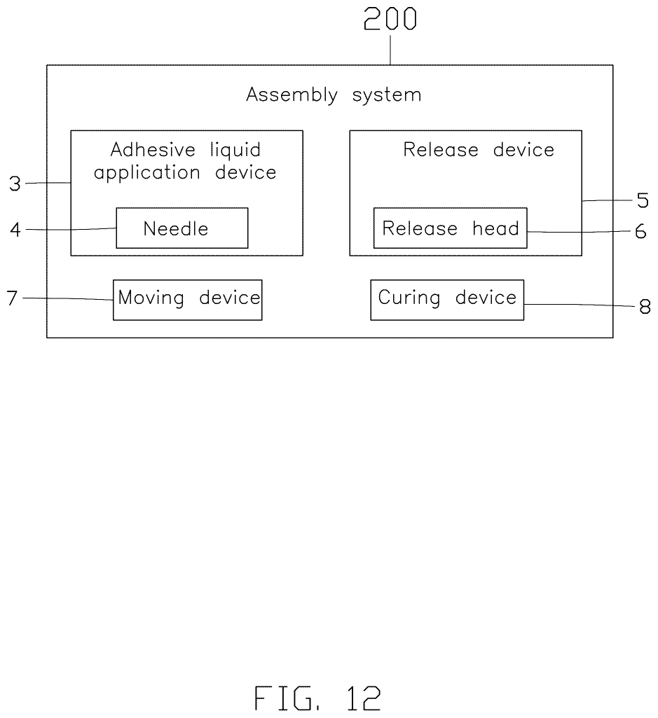

Black S3, referring to FIGS. 6 to 11, the microelectronic components 10 are transferred from a carrier plate 2 to the adhesive liquid droplets 20. The microelectronic components 10 are automatically aligned with the corresponding first areas 11 to complete the assembly of the microelectronic components 10 on the substrate 1.

In an embodiment, referring to FIG. 1D, a method for releasing the microelectronic components, and the assembling of the microelectronic components on the substrate 1 are provided by way of example. The method can begin at block S31.

Black S31, referring to FIG. 6, the carrier plate 2 is placed above the substrate 1 containing the adhesive liquid droplets 20, and the microelectronic components 10 are positioned such that the plurality of microelectronic components 10 one-to-one corresponds to the adhesive liquid droplets 20.

At this time, the substrate 1 and the carrier plate 2 are relatively stationary.

In an embodiment, the microelectronic components 10 can be fixed on the carrier plate 2 in advance, which can facilitate the assembly of microelectronic components 10, thereby improving the assembly efficiency.

In an embodiment, the carrier plate 2 includes a release layer 21, and the microelectronic components 10 are temporarily fixed on the carrier plate 2 through the release layer 21. For example, the release layer 21 may be but not limited to a hot melt adhesive layer.

Before the microelectronic components 10 on the carrier plate 2 are transferred to the adhesive liquid droplets 20, the method further comprises: temporarily fix the microelectronic components 10 on the release layer 21 of the carrier plate 2.

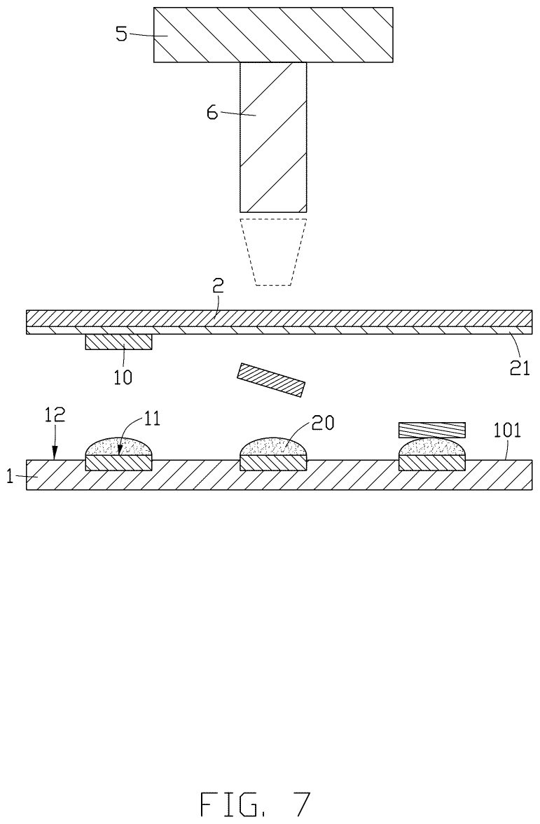

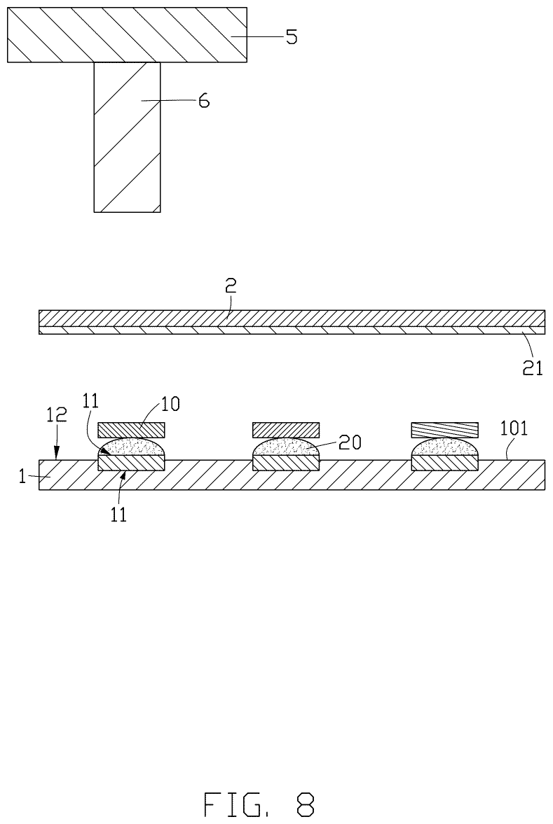

Black S32, referring to FIGS. 7 and 8, the microelectronic components 10 on the carrier plate 2 are released, so that the microelectronic components 10 may drop onto the corresponding adhesive liquid droplets 20.

In an embodiment, the microelectronic components 10 on the carrier plate 2 are released by a releasing device 5.

The carrier plate 2 and the substrate 1 are controlled to move relative to a release device 5. In an embodiment, the carrier plate 2 and the substrate 1 containing the adhesive liquid droplets 20 move under the release device 5. In another embodiment, the release device 5 moves above the carrier plate 2.

In an embodiment, the release device 5 may be a laser device. By controlling the laser device to emit laser beam, the laser beam is irradiated to the parts of the carrier plate 2 corresponding to the microelectronic components 10 to release the microelectronic components 10. The local temperature of the carrier plate 2 on which the microelectronic components 10 are mounted can be increased, such that the microelectronic components 10 pasted on the hot melt adhesive layer are released. The released microelectronic components 10 fall onto the corresponding adhesive liquid droplet 20 under the action of gravity.

In an embodiment, the microelectronic components 10 on the carrier plate 2 are arranged in an array. The release device 5 may include a plurality of release heads 6 such as laser devices, which are arranged side by side. Each release head 6 corresponds to at least one row of the microelectronic components 10. In this way, the release speed of the microelectronic components 10 can be increased, and the transfer and assembly speed of the microelectronic components 10 can be increased.

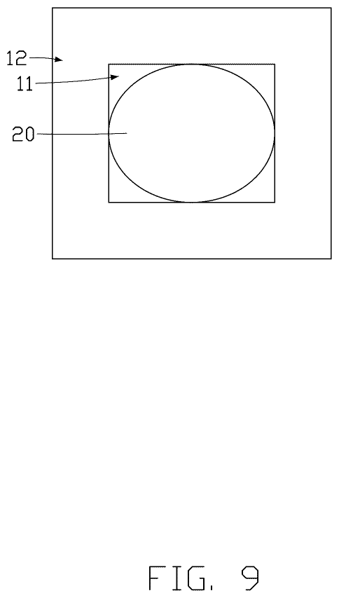

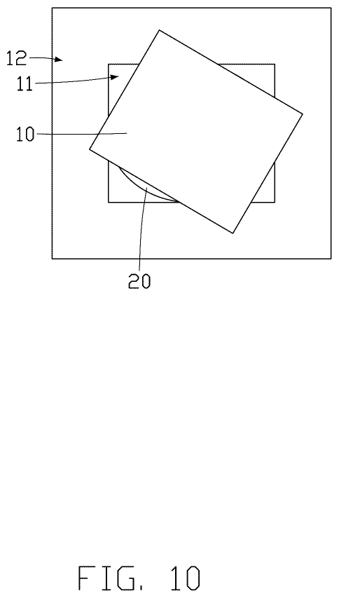

Black S33, referring to FIGS. 9 to 11, under the action of the surface tension of the adhesive liquid droplets 20, the microelectronic components 10 are automatically aligned with the first areas 11.

During the release of the microelectronic component 10, there may be a certain deviation. However, when the microelectronic component 10 falls on the adhesive liquid droplet 20, the adhesive liquid 20 also has a large wettability to the surface of the microelectronic component 10, and the shape and area of the first area 11 are basically the same as those of the microelectronic component 10. In this way, the adhesive liquid droplet 20 wets the surface of the microelectronic component 10. Under the surface tension of the adhesive liquid droplet 20, the microelectronic component 10 will automatically adjust its position and angle and align with the first area 11. That is, the adhesive liquid droplet 20 drives the microelectronic component 10 to align with the first area 11.

Black S34, referring to FIG. 1B, the adhesive liquid droplets 20 are cured to complete the assembly of the microelectronic components 10 on the substrate 1.

In an embodiment, when the adhesive liquids 20 are conductive adhesive liquid, the adhesive liquid droplets 20 are cured by heating.

The following example provides a detailed description of the assembly method for assembling Micro LEDs.

### EXAMPLE 1

Block 101, a substrate with wettability partitioning for MicroLEDs assembly was designed. The surface of the substrate had a plurality of first areas (super hydrophilic area) distributed in an array. The surface of the substrate also had a second area (super hydrophobic area) around each first area 11.

Block 102, the adhesive liquid was stored in the injection syringe of the adhesive liquid application device. The needle was driven to pass over the surface of the partitioned substrate through a precision moving platform. Under the capillary force on the surface of the partitioned substrate, the adhesive liquid was distributed on the first areas (super hydrophilic area) of the substrate and the adhesive liquid droplets were formed. The volume of the adhesive liquid droplet was controlled by adjusting the surface area of the first area on the substrate.

Block 103, laser device was used to locally heat the hot melt adhesive layer on the carrier plate to release the MicroLEDs form the carrier plate to fall onto the adhesive liquid droplets on the substrate. Under the action of the surface tensions of the adhesive liquid droplets, the MicroLEDs were automatically aligned with the super hydrophilic areas to realize the self-assembly of the MicroLEDs on the substrate.

Multiple injection needles were configured parallel with each other to realize the distribution of the adhesive liquids on the substrate. And multiple lasers were configured to realize rapid and massive release of MicroLEDs on the carrier plate. Thus, massive realized MicroLEDs were transferred and assembled on the substrate to form the MicroLED assembled structure.

Referring to FIG. 12, an assembly system 200 for performing the above assembly method is also provided according to an embodiment of the present disclosure. The assembly system 200 includes a moving device 7, an adhesive liquid application device 3 and a release device 5. The release device 5 can be a laser device. The assembly system 200 also includes a curing device 8.

The substrate 1 and the carrier plate 2 can be located on the moving device 7, and the carrier plate 2 is located above the substrate 1. According to actual needs, the moving device 7 can realize the relative movement of the substrate 1 and the carrier plate 2. The adhesive liquid application device 3 can move above the substrate 1 and inject adhesive liquid onto the first surface 101 of the substrate 1. The laser device is above the carrier plate 2 and can release the microelectronic components 10 on the carrier plate 2 by emitting laser beam. The curing device 8 can be used to realize the curing of the adhesive liquid droplets 20 to fix the microelectronic components 10 on the substrate 1.

With the above configuration, the assembly method and assembly system 200 provided according to the present disclosure can realize the rapid, accurate and large-scale transfer and assembly of microelectronic components 10 by forming the substrate 1 with different wettability zones, transferring the microelectronic components 10 onto the adhesive liquids 20 on the first area 11, and aligning the microelectronic components 10 with the corresponding first areas 11 under the action of the surface tension of the adhesive liquid droplets 20. Furthermore, the high efficiency and high yield of microelectronic components in large-scale assembly can be achieved. The operator or the release device 5 will not directly touch the surface of the Microelectronic components 10 during the transfer and assembly process, thereby improving the quality of the microelectronic components assembled structure 100. The self-alignment technology based on surface tension can achieve a high alignment accuracy within 1 um between the microelectronic component 10 and the first area 11. The method has low requirements for the initial position accuracy of the microelectronic components 10. When the microelectronic component 10 is released on the corresponding adhesive liquid droplet 20 of the first area 11 with high wettability, self-assembly can be realized. Moreover, there is no need to perform special treatment on the microelectronic components 10, and the requirements for the environment (such as electromagnetic interference, temperature, etc.) are low, and the ability to resist external interference is strong.

Furthermore, the transfer efficiency of microelectronic components 10 is high, and the transfer volume can be further increased by expanding the number of the needles 4 and the release heads 6 to realize massive transfer of microelectronic components 10.

In addition, the assembly system 200 with a simple structure is convenient to operate and has a lower cost. The operation accuracy of the assembly system 200 is low. The assembly system 200 can assemble massive microelectronic components 10 at the same time, and has stronger flexibility.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present exemplary embodiments, to the full extent indicated by the plain meaning of the terms in which the appended claims are expressed.

What is claimed is:

1. A method for assembling microelectronic components, the method comprising:
providing a substrate comprising a first surface, the first surface comprising a plurality of first areas and a second area surrounding the plurality of first areas, each of the plurality of first areas having a lyophilic surface, and the second area having a lyophobic surface;
forming a plurality of adhesive liquid droplets on the plurality of first areas; and
transferring a plurality of microelectronic components from a carrier plate to the plurality of adhesive liquid droplets, wherein the plurality of microelectronic components is aligned with the plurality of first areas, thereby the plurality of microelectronic components is assembled onto the substrate.

2. The method according to claim 1, wherein forming the plurality of adhesive liquid droplets on each of the plurality of first areas comprises:
applying adhesive liquid on the first surface of the substrate;
wherein a surface tension of the adhesive liquid on the plurality of first areas is different from a surface tension of the adhesive liquid on the second area, such that the adhesive liquid forms the plurality of adhesive liquid droplets on the plurality of first areas.

3. The method according to claim 1, wherein forming the plurality of adhesive liquid droplets on each of the plurality of first areas comprises:
applying adhesive liquid on the second area;
wherein a surface tension of the adhesive liquid on the plurality of first areas is different from a surface tension of the adhesive liquid on the second area, such that the adhesive liquid forms the plurality of adhesive liquid droplets on the second area, and the plurality of adhesive liquid droplets moves to the plurality of first areas.

4. The method according to claim 2, wherein applying the adhesive liquid on the first surface comprises:
applying the adhesive liquid on the first surface by an adhesive application device, wherein the adhesive application device comprises a plurality of needles arranged side by side above the substrate, each of the plurality of needles is configured to apply the adhesive liquid on the first surface.

5. The method according to claim 4, wherein applying the adhesive liquid on the first surface further comprises:
moving the adhesive application device relative to the substrate.

6. The method according to claim 4, wherein applying the adhesive liquid on the first surface further comprises:
moving the substrate relative to the adhesive application device.

7. The method according to claim 1, wherein the adhesive liquid is a conductive adhesive liquid.

8. The method according to claim 1, wherein transferring the plurality of microelectronic components from the carrier plate to the plurality of adhesive liquid droplets comprises:
placing the carrier plate above the substrate, and positioning the plurality of microelectronic components such that the plurality of microelectronic components one-to- one corresponds to the plurality of adhesive liquid droplets; and
releasing the plurality of microelectronic components on the carrier plate, such that the plurality of microelectronic components drops onto the plurality of adhesive liquid droplets.

9. The method according to claim 8, wherein releasing the plurality of microelectronic components on the carrier plate comprises:
releasing the plurality of microelectronic components on the carrier plate by a releasing device, wherein the plurality of microelectronic components on the carrier plate is arranged in an array, the release device comprises a plurality of release heads arranged side by side, and each of the plurality of release heads corresponds to at least one row of the plurality of microelectronic components.

10. The method according to claim 9, wherein the release device is a laser device.

11. The method according to claim 1, wherein before transferring the plurality of microelectronic components from the carrier plate to the plurality of adhesive liquid droplets, the method further comprises:
fixing the plurality of microelectronic components on a release layer of the carrier plate.

12. The method according to claim 11, wherein the release layer is a hot melt adhesive layer.

13. An assembly system for assembling microelectronic components, comprising:
a moving device configuring to move a substrate and/or move a carrier plate, wherein the substrate comprises a first surface, the first surface comprises a plurality of first areas and a second area surrounding the plurality of first areas, each of the plurality of first areas has a lyophilic surface, and the second area has a lyophobic surface, and the carrier plate is configured to fixed a plurality of microelectronic components;
an adhesive liquid application device configuring to apply adhesive liquid on the first surface, and form a plurality of adhesive liquid droplets on the plurality of first areas; and
a release device configuring to transfer the plurality of microelectronic components on the carrier plate onto the plurality of adhesive liquid droplets.

14. The assembly system according to claim 13, wherein the adhesive application device comprises a plurality of needles arranged side by side above the substrate, each of the plurality of needles is configured to apply adhesive liquid on the first surface.

15. The assembly system according to claim 13, wherein the plurality of microelectronic components on the carrier plate is arranged in an array, the release device comprises a plurality of release heads arranged side by side, and each of the plurality of release heads corresponds to at least one row of the plurality of microelectronic components.

16. The assembly system according to claim 15, wherein the release device is a laser device.

17. The assembly system according to claim 13, further comprising a curing device configuring to cure the plurality of adhesive liquid droplets.
